(19) United States
(12) Patent Application Publication
(10) Pub. No.: US 2012/0081172 A1
(43) Pub. Date: Apr. 5, 2012

(54) High Voltage Switch Suitable for Use in Flash Memory

(76) Inventors: Jonathan Hoang Huynh, San Jose, CA (US); Feng Pan, Fremont, CA (US)

(21) Appl. No.: 12/895,476

(22) Filed: Sep. 30, 2010

(51) Int. Cl. H03K 17/687

(52) U.S. Cl. 327/437

(57) ABSTRACT

A high voltage switch is presented that, rather than relying upon a charge pump to boost the voltage applied to the switches gate in order to compensate for the switch's threshold voltage, a combination of high voltage devices to eliminate the threshold voltage from the switch. This will save on the needed circuit area and reduce the current and, consequently, power consumption. In the exemplary embodiment, the switch circuit passes an input voltage from an input node to an output node in response to an enable signal. The switch includes a level shifter connected to the input node and is connected to receive the enable signal to provide the input voltage as output when the enable signal is asserted. The circuit also includes a first depletion type NMOS transistor that is connected between the input node and a first intermediate node and having a gate connected to receive the output of the level shifter, and a PMOS transistor that is connected between the first intermediate node and the output node and having a gate connected to receive an inverted form of the enable signal.

### BACKGROUND

1. Field of the Invention

This application relates generally to integrated circuit semiconductor devices, and, more specifically, to high voltage switches.

2. Background Information

In an integrated circuit, it is common to need a circuit to provide a voltage from a source to an output in response to an input signal. An example of such a switch is a word line select circuit of in a non-volatile memory. In such a circuit, a relatively high programming voltage is supplied to a word line in response to an input signal at the device to device logic level. For example, in fairly typical values for a NAND type FLASH memory, 10-30V is provided on a word line in response to an input going from ground to “high” value of 3-5V. In flash memory, many different high voltages are applied to the word lines for different program, verify, read, and erase operations. The goal is to have switch which can fully pass the voltage without any DC leakage path. Each high voltage applied on a word line is typically passed through a switch which requires a higher supply (often through use of a local charge pump) to turn fully on the switch. Such complexity contributes to bigger die size and power consumption.

FIG. 1a shows an example of such an arrangement, with a corresponding set of waveforms shown in FIG. 1b. In the switching circuit 100, the object to fully pass the input voltage Vin through the switch of transistor HVN 101 as the output voltage. To overcome the threshold voltage of the switch 101, a charge pump 103 is used to generate a voltage TO_OUT that is greater than the threshold voltage HVN 101. This is shown in FIG. 1b, where the input voltage Vin is first raised from Vdd (typically 1.8 to 2.2V) to the desired level of VHIGH, which may be on the order of 10-30V. Vin is also supplied to the pump 103, as is the enable signal. When the enable signal is asserted, the output TG_OUT of the pump then goes to HHIGH+Vt, where Vt is the threshold voltage of HNV 101. TG_OUT is supplied to the gate of HVN, which they turned on sufficiently to fully pass the high voltage as Vout. Although this arrangement fully passes the desired voltage, it is at the cost of die size and current consumption due the need for the charge pump 103. Consequently, there is an ongoing need for level shifter circuits capable of handling high

### SUMMARY OF THE INVENTION

According to a general aspect of the invention, a switch circuit for passing an input voltage from an input node to an output node in response to an enable signal. The switch includes a level shifter connected to the input node and is connected to receive the enable signal to the input voltage as output when the enable signal is asserted. The circuit also includes a first depletion type NMOS transistor that is connected between the input node and a first intermediate node and having a gate connected to receive the output of the level shifter, and a PMOS transistor that is connected between the first intermediate node and the output node and having a gate connected to receive an inverted form of the enable signal.

Various aspects, advantages, features and embodiments of the present invention are included in the following description of exemplary examples thereof, which description should be taken in conjunction with the accompanying drawings. All patents, patent applications, articles, other publications, documents and things referenced herein are hereby incorporated herein by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWINGS

FIG. 1a is an example of a high voltage switch.

FIG. 1b is a set of waveforms illustrating the operation of the switch of FIG. 1a.

FIG. 2a is an exemplary embodiment for a high voltage switch.

FIG. 2b is a set of waveforms illustrating the operation of the switch of FIG. 2a.

FIGS. 3a-c are embodiments of a detail of FIG. 2a.

FIG. 4 illustrates some possible arrangements for the well connection of a device in FIGS. 3a and 3b.

### DETAILED DESCRIPTION

As noted in the Background, previous approaches for providing a high voltage switch circuit have typically relied upon a charge pump to boost the voltage applied to the switches gate in order to compensate for the switch's threshold voltage. This approach has the disadvantage of the current and area requirements of the charge pump, particular when boosting sufficiently to pass voltages in the 10-30 volt range. According to principle aspects of the techniques presented here, the switch is replaced by a combination of high voltage devices to eliminate the threshold voltage from the switch. With the change, a charge pump is no longer needed to pass fully the input voltage without leakage and only a level-shifter is required. This will save on the needed circuit area and reduce the current and, consequently, power consumption.

Such switches find many applications in integrated circuits when there is a need to provide a particular voltage at a given node in response to an enable signal. For example, they frequently occur as part of the peripheral circuitry on non-volatile memory devices where they may need to supply some of the fairly high voltage levels. Examples of such non-volatile memory devices are described in U.S. Pat. Nos. 5,570,315, 5,903,495, and 6,046,935. And although the following discussion is presented in terms of high voltage applications, the switch designs presented below readily apply to other applications, such as power regulators, for instance.

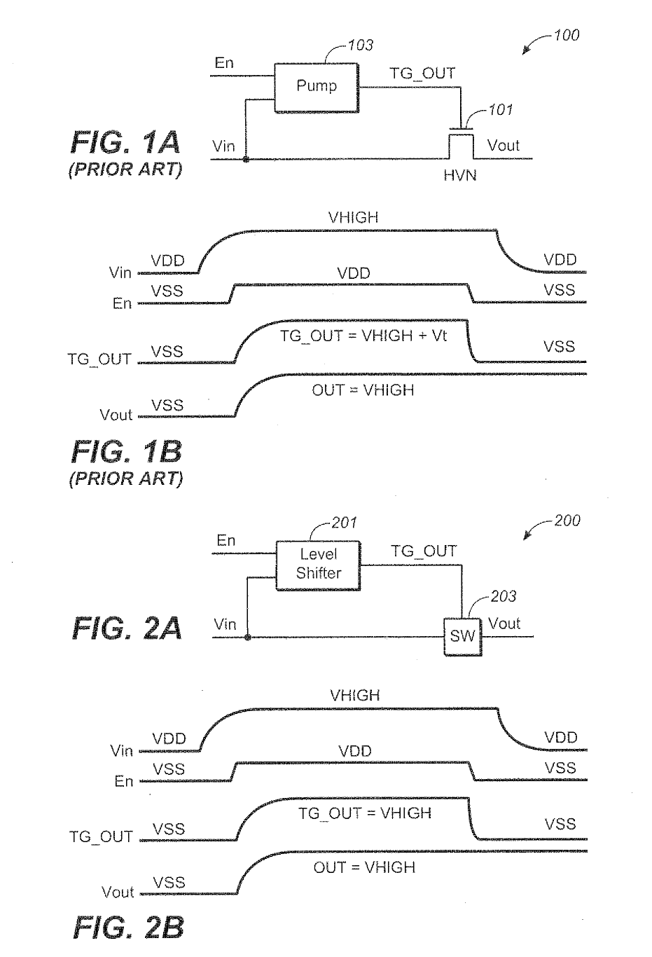

FIG. 2a is a box diagram of an exemplary embodiment of such switching circuitry. The circuit 200 includes a switch SW 203 connected between the input and output nodes. The switch is controlled by the output of the level shifter 201, which is connected to receive the enable signal EN as well as the input voltage Vin and supply the output TG_OUT, which is used to control the switch SW 203. The level shifter 201 is such that when the enable signal EN is not asserted, TG_OUT is the low voltage level on the integrated circuit (Vss or ground); and when EN is asserted the high input voltage Vin=VHIGH is the output, TGPUT=VHIGH. An example of a suitable level shifter is presented in a US patent application entitled “Level Shifter with Shoot-Through Current Isolation”, by Huynh et al., filed concurrently with the present application. The switch 203 is constructed so that the full value of VHIGH is passed when TG_OUT=VHIGH, in contrast to the arrangement of FIG. 1a that required a boosted value to be applied to the switch.

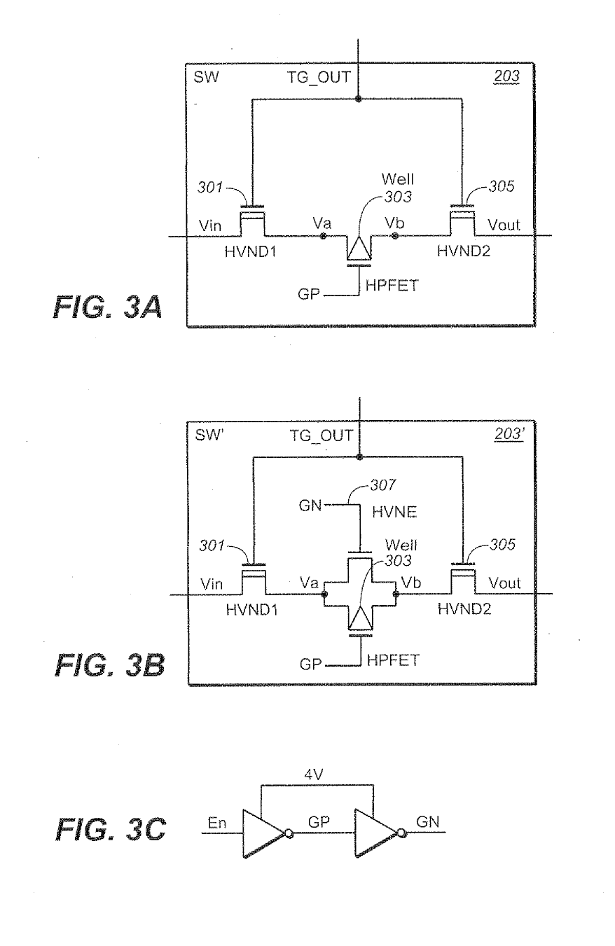

FIGS. 3a and 3b present embodiments of such a switch. Considering FIG. 3a first, the switch SW 203 includes a depletion type NMOS transistor HVND1 301 in series with a PMOS transistor HPFET 303 between the Vin node and the Vout node, with the HVND1 301 on the Vin side. A second depletion type NMOS device HVND2 305 is also connected in series between HPFET 303 and the Vout node, which is optional, but can be used to prevent current flowing back in to the switch from the Vout node, as discussed further below. The gates of HVND1 301 and HVND2 305 are connected to TG_OUT. The gate of HPFET 303 is connected to a signal GP, which an inverted form of the enable signal EN, raised up to a value sufficient to properly turn off the PMOS 303. An example of a circuit to do this is shown in FIG. 3c, which also provides a further inverted signal GN discussed below with FIG. 3b. In this example, OP (and UN) use high and low values of 4 volts and Vss or ground, whereas the high value of EN will be Vdd, which is here in the range of 1.8 to 2.2 volts. The Well connection will be discussed further below.

The exemplary embodiment of the switching circuit 200 is for use with high voltages and, consequently, the transistors HVND1 301, HPFET 303, and FIVND2 305 are all high voltage devices. In the arrangement of FIG. 3a for switch 203, the switch will only pass voltages when Vin=Vout>Vt, the threshold voltage of HPFET 303. To pass all voltage ranges, includes those below the threshold voltage of HPFET 303, the SW 203 can be modified as shown in FIG. 3b.

In the variation of FIG. 3b, the switch SW is modified as shown by SW′ 203′. An enhancement type NMOS HVNE 307 is added in parallel with HPFET 303 between HVND1 301 and, via FIVND2 305, the Vout node, where the second depletion type NMOS HVND2 305 is again optional. The gate of HVNE receives the signal GN, which is the inverse of GP and can be provided from a circuit such as is shown in FIG. 3c. In this way, when EN is asserted, both HVNE 307 and HPFET 303 will be turned on and will pass the full voltage range. Consequently, the arrangement of 203′ in FIG. 3b can be used when the switch is also wanted to pass voltages below the threshold of HPFET 303.

FIG. 2b shows set of waveforms for the operation of the circuit of FIG. 2a. To enable the switch, after Vin is taken from Vdd to VHIGH, EN is brought up from VSS to VDD. The level shifter 201 will then bring TG_OUT up to the same level as VIN. As TG_OUT increases to Vin and the gate voltages switch, GP (from 4V to VSS) and GN (from VSS to 4V), the resistance of the path from Vin to Vout decreases, allowing current to flow from Vin to Vout.

To disable the switching block 200, EN is taken back to ground (Vss), taking the output of the level shifter 201 at TG_OUT Vss as well. With TG_OUT is VSS, the nodes Va and Vb (on either side of HPFET 303 in FIG. 3a, of the pair HPFET 303 and HVNE 307 in FIG. 3b) are limited to have maximum value equal to the threshold voltage VTD of the depletion devices (301, 305) on either side. As EN=Vss, the gate nodes GP and GN are brought to a voltage higher than VTD and Vss respectively (see FIG. 3c). This effectively shuts off the path from Vin to Vout, so that there will be no DC leakage path. The value of Vin can then be lowered back to Vin as desired. (Vout is shown to stay at VHIGH as the switch SW 203 is now off, trapping the charge on, in the exemplary embodiment, a word line, but it may of course be drained or leak off by other pathways.)

In both. FIGS. 3a and 3b, a second high voltage NMOS transistor of the depletion type HVND2 305 is connected between the node Vb and the Vout node. This transistor can prevent current from flowing back in to the switch 200 from the Vout node. This situation could otherwise occur when the switch 200 is disabled (EN being low in the exemplary embodiment), but where a high enough voltage is present on the Vout node. To consider an example of where this may occur, consider the exemplary application where the switch 200 is used to supply the voltage Vin in response to the signal EN to a word line in a non-volatile memory. Such non-volatile memories may use a number of different word line voltages for various read, write, verify, and erase operations. (See the cited reference above for more detail.) Consequently, there may be a number of such switches as 200, each with a corresponding Vin and EN, having their respective Vout nodes coupled to the word line. This could result one switch being disabled (with its EN signal de-asserted), but with another such switch being enabled to supply its VHIGH on the word line, and also consequently at the Vout node of the first, disabled switch. Without the HVND2 305 device, the VHIGH from the second, enabled switch could then flow back into the first, disabled switch from its Vout node. In application where this sort of situation is not a concern, HVND2 305 can be left out; but in application where the switch block 200 may be biased so that the level at Vout is greater that the level at Vin, HVND2 305 can be added to limit the current and the voltage to node Vb and allow HPFET 303 to completely shut off.

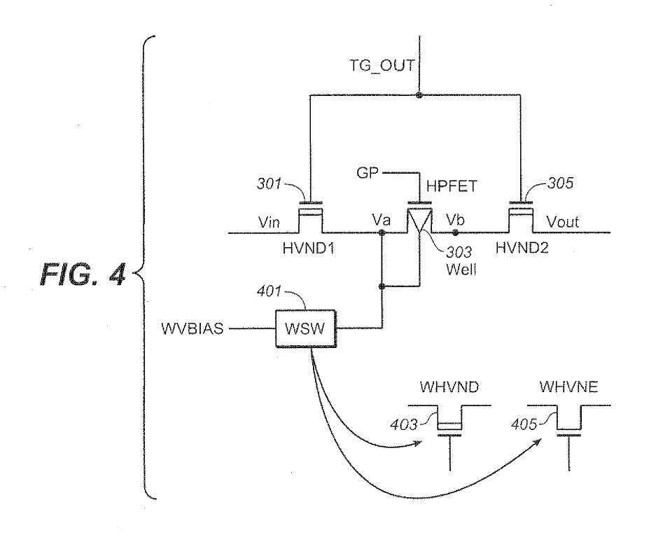

Concerning the Well connection of HPFET 303 in FIGS. 3a and 3b, several options are available for the exemplary embodiments. In most cases, this will be connected to one of the higher available voltages. One possible connection is to arrange for the Well connection to be to the higher of the nodes Va and Vb. This may result in the connection be switched between the Va node when the switch is enabled and the Vb node when disabled. When several switches are being used to supply a word line, as described in the preceding paragraph, the Well connection for all of the switches can be taken as the highest of different VHIGH values used among the switches. An alternate Well connection for HPFET 303 is shown in FIG. 4.

FIG. 4 shows an alternate Well connection for HPFET 303 that can used when the Well connection cannot be biased higher than Vin of the switch. This arrangement can be useful in applications where the switch block 200 may be biased so that Vout is higher than Vin. (FIG. 4 uses an arrangement for SW 203 as shown in FIG. 3a, but similar remarks apply to SW′ 203′ of FIG. 3b.) As shown in FIG. 4, the Well connection of HPFET 303 is connect to the node Va and also to the output of the well switch WSW 401, which has as its input WVBIAS. The level of WVBIAS can be the level of the external supply voltage VEXT or from another pump supply and should have a value higher than the threshold values of the of HVND1 301 and HVND2 305 devices. The added well bias switch WSW 401 can be implemented in a number of ways, including embodiments such as a depletion type NFET WHVND 403 or the enhancement type NFET WHVNE 405, where these would again be high voltage device for the exemplary high voltage applications. For example, if the NFET WHVND 403 is used, the gate values for on could be a high value of Vdd and for off could be the low value of 0V; if the NFET WHVNE 405 is used, the gate values for on could be a high value of 4V+Vt and for off could be the low value of 0V, where, in either case the gate level should have the same polarity as the signal GP (opposite to EN). When the switch 200 is enabled, the Well will be at the level of Va, and the switch WSW 401 will be off and the switch will operate as previously described. When the switch block 200 is disabled, the well biasing switch WSW will be on, and the node WELL (and Va) can be biased to a voltage above the threshold values of HVND1 301 device (for example, WVBIAS=4V). The node Vin will then be reset to a voltage above the threshold values of HVND1 301 or left to float to avoid leakage current.

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application, to thereby enable others skilled in the art to best utilize the invention in various embodiments and with various modifications as are suited to the particular use contemplated. It is intended that the scope of the invention be defined by the claims appended hereto.

It is claimed:

1. A switch circuit for passing an input voltage from an input node to an output node in response to an enable signal, the switch comprising:
a level shifter connected to the input node and connected to receive the enable signal, and providing the input voltage as output when the enable signal is asserted;
a first depletion type NMOS transistor connected between the input node and a first intermediate node and having a gate connected to receive the output of the level shifter; and
a PMOS transistor connected between the first intermediate node and the output node and having a gate connected to receive an inverted form of the enable signal.

2. The switch circuit of claim 1, further comprising:
a second depletion type NMOS transistor having a gate connected to receive the output of the level shifter and through which the PMOS transistor is connected to the output node.

3. The switch circuit of claim 2, wherein the second depletion type NMOS transistor is connected to the PMOS transistor through a second intermediate node and the switch connects the well of the PMOS transistor to the one of the first and second intermediate nodes that is at the higher voltage level.

4. The switch circuit of claims 2, wherein said switch circuits is one of a plurality of switch circuits each connected between the output node and a respective input node, each having a corresponding independently settable input voltage level and a corresponding independently settable enable signal, and wherein the well of the PMOS transistor is connected to receive the highest of the independently settable input voltage levels.

5. The switch circuit of claim 2, further comprising:
a well bias circuit connected to receive a biasing voltage and having an output connected to the well of the PMOS transistor and to the first intermediate node, where the well bias circuit passes the biasing voltage to the output when the enable signal is de-asserted.

6. The switch circuit of claim 5, wherein the biasing voltage has a value higher than the threshold voltage of the first depletion type NMOS transistor.

7. The switch circuit of claim 5, wherein the input voltage is set to have a value higher than the threshold voltage of the first depletion type NMOS transistor when the enable signal is de-asserted.

8. The switch circuit of claim 5, wherein the input voltage is set to float when the enable signal is de-asserted.

9. The switch circuit of claim 1, wherein the inverted form of the enable signal supplied to the gate of the PMOS transistor has a high value of a greater voltage than the high value of the enable signal.

10. The switch circuit of claim 1, further comprising:
a NMOS transistor connected in parallel with the PMOS transistor between the first intermediate node and the output node and having a gate connected to receive a form of the enable signal.

11. The switch circuit of claim 10, wherein the form of the enable signal supplied to the gate of the NMOS transistor connected in parallel with the PMOS transistor has a high value of a greater voltage than the high value of the enable signal.

12. The switch circuit of claim 1, wherein the switch circuit is formed as a peripheral element on a non-volatile memory circuit and the output node is connectable to supply a word-line of a memory array.

13. The switch circuit of claim 1, wherein the input voltage is in the range of from 10 to 30 volts.

14. The switch circuit of claim 1, wherein the PMOS transistor and the first depletion type NMOS transistor are high voltage devices.
